(19) United States
(12) Patent Application Publication
(10) Pub. No.: US 2020/0058731 A1
(43) Pub. Date: Feb. 20, 2020

(54) SEMICONDUCTOR DEVICE

(71) Applicant: Samsung Electronics Co., Ltd., Suwon-si (KR)

(72) Inventors: Hyo-sik MUN, Hwaseong-si (KR); Sang-yeol KANG, Yongin-si (KR); Eun-sun KIM, Suwon-si (KR); Young-lim PARK, Anyang-si (KR); Kyoo-ho JUNG, Seoul (KR); Kyu-ho CHO, Seoul (KR)

(73) Assignee: Samsung Electronics Co., Ltd., Suwon-si (KR)

(21) Appl. No.: 16/539,454

(22) Filed: Aug. 13, 2019

(30) Foreign Application Priority Data
Aug. 14, 2018 (KR) 10-2018-0094970
Feb. 20, 2019 (KR) 10-2019-0020052

(51) Int. Cl. H01L 49/02; H01L 27/108

(52) U.S. Cl. CPC H01L 28/65; H01L 27/1085; H01L 27/10805; H01L 28/75

(57) ABSTRACT

A semiconductor device includes a lower electrode on a substrate, a dielectric layer structure on the lower electrode and including hafnium oxide having a tetragonal crystal phase, a template layer on the dielectric layer structure and including niobium oxide (NbOₓ, 0.5≤x≤2.5), and an upper electrode structure including a first upper electrode and a second upper electrode on the template layer.

### CROSS-REFERENCE TO RELATED APPLICATION

This application claims the benefit of Korean Patent Applications No. 10-2018-0094970, filed on Aug. 14, 2018, and No. 10-2019-0020052, filed on Feb. 20, 2019, in the Korean Intellectual Property Office, the disclosure of which is incorporated herein in its entirety by reference.

### BACKGROUND

The inventive concepts relate to a semiconductor device, and more particularly, to a semiconductor device including a capacitor structure.

As semiconductor devices have been downscaled, the size of a capacitor structure of a DRAM device has also been reduced. However, even though the size of the capacitor structure is reduced, the capacitance required for each unit cell of the DRAM device has the same value. Accordingly, a high-k dielectric material having a high dielectric constant and a metal-insulator-metal (MIM) capacitor using a metal electrode have been proposed.

### SUMMARY

The inventive concepts provide a semiconductor device including a capacitor structure having a high capacitance.

According to an aspect of the inventive concepts, there is provided a semiconductor device including a lower electrode on a substrate, a dielectric layer structure on the lower electrode and including hafnium oxide having a tetragonal crystal phase, a template layer on the dielectric layer structure and including niobium oxide (NbOₓ, 0.5≤x≤2.5), and an upper electrode structure including a first upper electrode and a second upper electrode on the template layer.

According to another aspect of the inventive concepts, there is provided a semiconductor device including a lower electrode structure on a substrate and including a first lower electrode and a second lower electrode, a template layer on the lower electrode structure and including niobium oxide (NbOₓ, 0.5≤x≤2.5), a dielectric layer structure on the template layer and including hafnium oxide having a tetragonal crystal phase, and an upper electrode structure on the dielectric layer structure.

According to another aspect of the inventive concepts, there is provided a semiconductor device including a contact structure on a substrate and a capacitor structure on the contact structure. The capacitor structure includes a lower electrode electrically connected to the contact structure, a dielectric layer structure on the lower electrode and including hafnium oxide having a tetragonal crystal phase, a template layer on the dielectric layer structure and including niobium oxide (NbOₓ, 0.5≤x≤2.5), and an upper electrode structure including a first upper electrode and a second upper electrode on the template layer.

### BRIEF DESCRIPTION OF THE DRAWINGS

Embodiments of the inventive concepts will be more clearly understood from the following detailed description taken in conjunction with the accompanying drawings in which:

FIG. 1 is a cross sectional view illustrating a semiconductor device according to example embodiments;

FIG. 2 is a cross sectional view illustrating a semiconductor device according to example embodiments;

FIG. 3 is a cross sectional view illustrating a semiconductor device according to example embodiments;

FIG. 4 is a cross sectional view illustrating a semiconductor device according to example embodiments;

FIG. 5 is a cross sectional view illustrating a semiconductor device according to example embodiments;

FIG. 6 is a cross sectional view illustrating a semiconductor device according to example embodiments;

FIG. 7 is a cross sectional view illustrating a semiconductor device according to example embodiments;

FIG. 8 is a layout diagram illustrating a semiconductor device according to example embodiments;

FIG. 9 is a cross sectional view taken along the line B-B′ in FIG. 8;

FIG. 10 is an enlarged view of a CX1 portion of FIG. 9;

FIG. 11 is a cross sectional view illustrating a semiconductor device according to example embodiments;

FIG. 12 is a cross sectional view illustrating a semiconductor device according to example embodiments;

FIG. 13 is a flowchart schematically illustrating a method of manufacturing a semiconductor device according to example embodiments;

FIG. 14 is a flowchart schematically illustrating a method of manufacturing a semiconductor device according to example embodiments;

FIGS. 15 to 24 are cross-sectional views illustrating a method of manufacturing a semiconductor device according to example embodiments in accordance with a process order;

FIGS. 25a to 25c are graphs schematically showing the element content contained in the semiconductor device according to example embodiments; and

FIG. 26 is an X-ray diffraction analysis graph of a semiconductor device according to experimental examples and comparative examples.

### DETAILED DESCRIPTION OF EMBODIMENTS

Hereinafter, example embodiments of the technical idea of the inventive concepts will be described in detail with reference to the accompanying drawings.

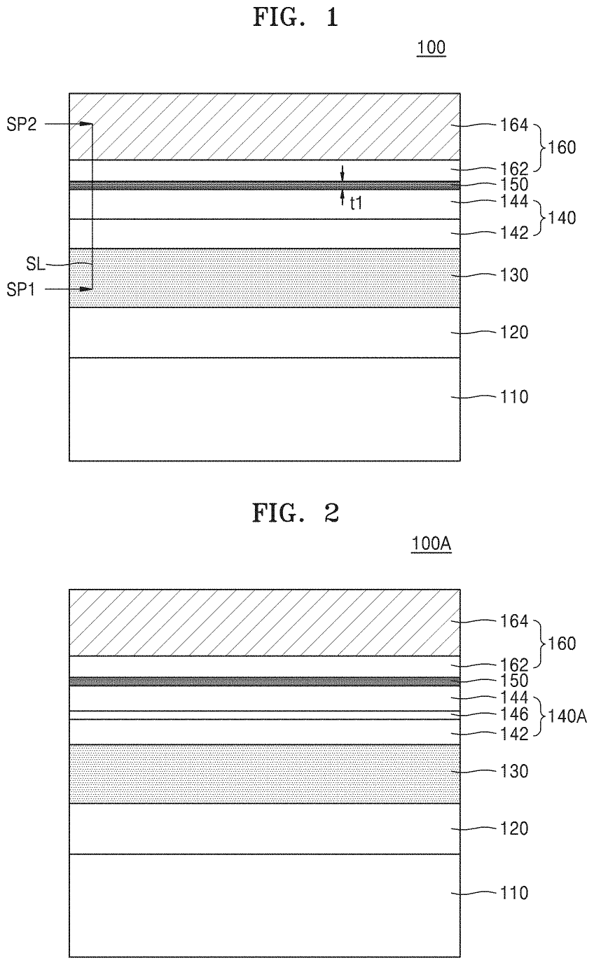

FIG. 1 is a cross-sectional view illustrating a semiconductor device 100 according to example embodiments.

Referring to FIG. 1, the semiconductor device 100 may include a substrate 110, an interlayer insulating film 120, a lower electrode 130, a dielectric layer structure 140, a template layer 150, and/or an upper electrode structure 160.

The substrate 110 may include a semiconductor material such as silicon (Si), germanium (Ge), silicon germanium (SiGe), silicon carbide (SiC), gallium arsenide (GaAs), indium arsenide (InAs), indium phosphide (InP).

An interlayer insulating film 120 may be placed on the substrate 110. The interlayer insulating film 120 may include silicon oxide, silicon nitride, silicon oxynitride, or the like. A wiring structure including a plurality of conductive layers and insulating layers, or a gate structure including a plurality of conductive layers and insulating layers may be further placed on the substrate 110, and the interlayer insulating film 120 may be placed to cover the wiring structure or the gate structure.

The lower electrode 130 may be placed on the interlayer insulating film 120. The lower electrode 130 may include at least one selected from a metal such as ruthenium (Ru), titanium (Ti), tantalum (Ta), niobium (Nb), iridium (Jr), molybdenum (Mo), tungsten (W), a conductive metal nitride such as titanium nitride (TiN), tantalum nitride (TaN), niobium nitride (NbN), molybdenum nitride (MoN), tungsten nitride (WN), and a conductive metal oxide such as iridium oxide.

In example embodiments, the lower electrode 130 may include a single material layer or a stacked structure of a plurality of material layers. In an example embodiment, the lower electrode 130 may include a single layer of titanium nitride (TiN), or a single layer of niobium nitride (NbN). In another example embodiment, the lower electrode 130 may include a stacked structure including a first lower electrode layer including titanium nitride (TiN) and a second lower electrode layer including niobium nitride (NbN).

The dielectric layer structure 140 may be placed on the lower electrode 130. The dielectric layer structure 140 may include a first dielectric layer 142 and a second dielectric layer 144 which are sequentially placed on the lower electrode 130.

The first dielectric layer 142 may include a first dielectric material. The first dielectric material may include a high-k material having a higher dielectric constant than silicon oxide. For example, the first dielectric material may include at least one of zirconium oxide, aluminum oxide, aluminum silicon oxide, titanium oxide, yttrium oxide, scandium oxide, and lanthanide oxide, but is not limited thereto.

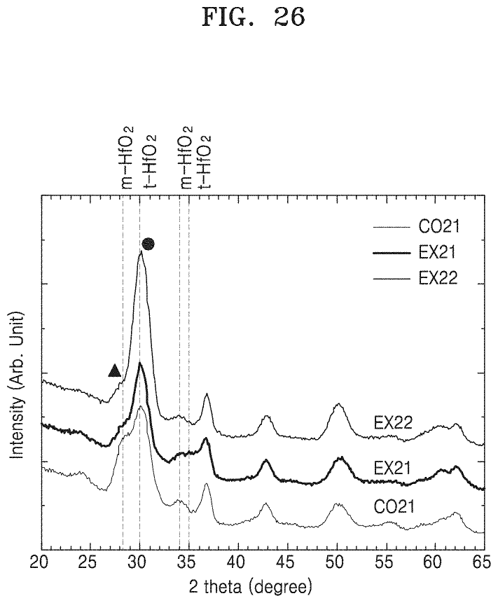

The second dielectric layer 144 may include a second dielectric material different from the first dielectric material and the second dielectric material may include a metal oxide having a higher dielectric constant than the first dielectric material. For example, the second dielectric material may include hafnium oxide having a tetragonal crystalline phase. For example, the dielectric layer structure 140 may exhibit a peak at 30.48°±0.2° from the {101} plane of a tetragonal crystal structure of the second dielectric layer 144 in an X-ray diffraction analysis (see FIG. 26). The hafnium oxide having the tetragonal crystal phase may exhibit a dielectric constant as high as about 30% as compared to the hafnium oxide having a monoclinic crystalline phase. In other words, a dielectric constant of the hafnium oxide having the tetragonal crystal phase may be greater than about 130% of a dielectric constant of the hafnium oxide having a monoclinic crystalline phase. As the second dielectric layer 144 includes hafnium oxide having a tetragonal crystal phase, the total dielectric constant of the dielectric layer structure 140 may be relatively high.

A template layer 150 may be placed on the dielectric layer structure 140. The template layer 150 may be placed in contact with the second dielectric layer 144 on the entire surface of the second dielectric layer 144. The template layer 150 may serve to help preferentially orient a material layer (e.g., the second dielectric layer 144 of the dielectric layer structure 140) in contact with the template layer 150 to a crystalline phase having a particular crystal structure. For example, the template layer 150 may act as a crystallization-inducing layer that helps the second dielectric layer 144 crystallize into a hafnium oxide with a tetragonal crystal phase during a subsequent heat treatment process. In addition, the template layer 150 may acts as a protective layer to reduce or prevent damage to the dielectric layer structure 140 or penetration of materials such as reactants including nitrogen into the dielectric layer structure 140 during the process of forming the upper electrode structure 160.

In example embodiments, the template layer 150 may include an oxide of a first metal. For example, the template layer 150 may include niobium oxide (NbOₓ, 0.5≤x≤2.5). In other example embodiments, the template layer 150 may include niobium oxide doped with nitrogen at a constant concentration. In example embodiments, a first thickness t1 of the template layer 150 may be from about 1 to about 10 angstroms (Å), but is not limited thereto. In example embodiments, the template layer 150 may have conductivity, but is not limited thereto.

The upper electrode structure 160 may be placed on the template layer 150. The upper electrode structure 160 may have a stacked structure of a first upper electrode 162 and a second upper electrode 164.

The first upper electrode 162 may be formed directly on a top portion of the template layer 150 and may include a first metal or a nitride of the first metal. In example embodiments, the first upper electrode 162 may include niobium nitride (NbN_{y}, 0.5≤y≤1.0).

In an example fabrication process, a first upper electrode 162 may be formed using niobium nitride on the dielectric layer structure 140, and in this case, a portion of the first upper electrode 162 in contact with the dielectric layer structure 140 may be oxidized to form the template layer 150. In this case, for example, a first thickness t1 of the template layer 150 may be about 5 Å or less.

In other example fabrication process, the template layer 150 may be formed first using niobium oxide on the dielectric layer structure 140 and then the first upper electrode 162 may be formed using niobium nitride on the template layer 150.

The second upper electrode 164 may include at least one of a metal material such as a doped silicon, a doped silicon germanium, ruthenium (Ru), titanium (Ti), tantalum (Ta), niobium (Nb), iridium (Jr), molybdenum (Mo), tungsten (W), a conductive metal nitride such as titanium nitride (TiN), tantalum nitride (TaN), niobium nitride (NbN), molybdenum nitride (MoN), tungsten nitride (WN), and a conductive metal oxide such as iridium oxide.

According to the semiconductor device 100 described above, the template layer 150 may be placed between the dielectric layer structure 140 and the upper electrode structure 160, and in particular, the template layer 150 may be formed between the first upper electrode 162 and the second dielectric layer 144 with a first thickness t1 that is relatively thin. Due to the template layer 150, the second dielectric layer 144 may have a tetragonal crystal phase, and thus the dielectric layer structure 140 may have a relatively high total dielectric constant. In addition, the template layer 150 may also acts as a protective layer to reduce or prevent damage to the dielectric layer structure 140 or penetration of materials such as reactants including nitrogen into the dielectric layer structure 140 during the process of forming the upper electrode structure 160. Thus, the semiconductor device 100 may have high capacitance and excellent electrical characteristics.

FIG. 2 is a cross-sectional view illustrating a semiconductor device 100A according to example embodiments. In FIG. 2, the same reference numerals as in FIG. 1 denote the same elements. The semiconductor device 100A may be the same as the semiconductor device 100 described with reference to FIG. 1 except for a configuration of the dielectric layer structure 140A. Thus, the above-described difference will be mainly described.

Referring to FIG. 2, the dielectric layer structure 140A may include a first dielectric layer 142, a second dielectric layer 144, and a third dielectric layer 146. The first dielectric layer 142 may on the lower electrode 130 and the second dielectric layer 144 may be placed in contact with the template layer 150, and the third dielectric layer 146 may be interposed between the first dielectric layer 142 and the second dielectric layer 144.

The third dielectric layer 146 may include a third dielectric material, and the third dielectric material may be different from the first dielectric material included in the first dielectric layer 142 and the second dielectric material included in the second dielectric layer 144. In example embodiments, the third dielectric material may include a high-k material having a higher dielectric constant than silicon oxide. For example, the third dielectric material may include at least one of zirconium oxide, aluminum oxide, aluminum silicon oxide, titanium oxide, yttrium oxide, scandium oxide, and lanthanide oxide, but is not limited thereto.

In example embodiments, the third dielectric layer 146 may be interposed between the first dielectric layer 142 and the second dielectric layer 144 to reduce a surface roughness of the first dielectric layer 142 or to reduce a leakage current through the first dielectric layer 142. However, the example embodiments are not limited to the above description. In an example embodiment, the first dielectric layer 142 may include zirconium oxide (ZrOₓ), and the third dielectric layer 146 may include aluminum oxide (AlOₓ) or aluminum zirconium oxide (AlₓZr_{y}O_{z}), but is not limited thereto.

According to the above-described semiconductor device 100A, the second dielectric layer 144 may be formed of a hafnium oxide having a tetragonal crystal phase by the template layer 150, and thus the dielectric layer structure 140A may have a relatively high total dielectric constant.

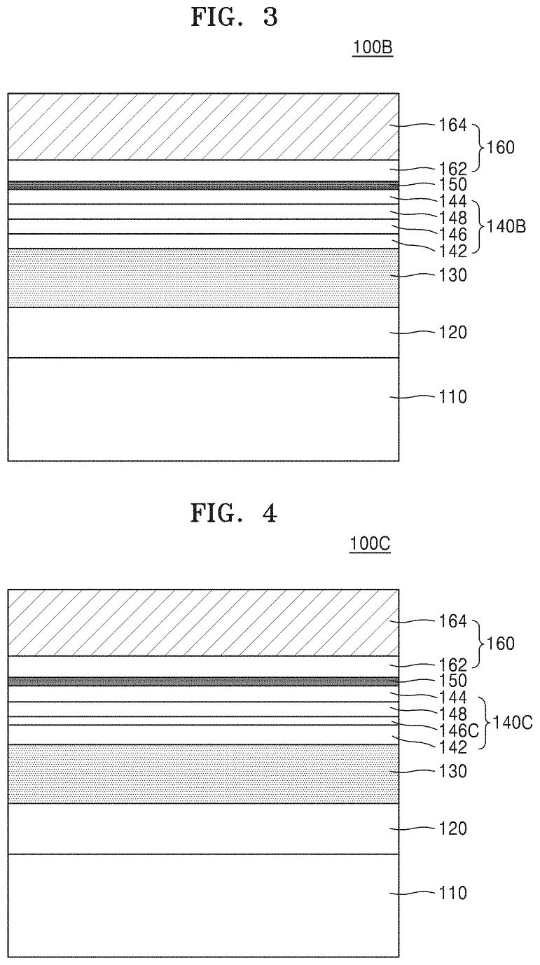

FIG. 3 is a cross-sectional view illustrating a semiconductor device 100B according to example embodiments. In FIG. 3, the same reference numerals as in FIGS. 1 and 2 denote the same elements. The semiconductor device 100B may be the same as the semiconductor device 100 described with reference to FIG. 1 except for the configuration of the dielectric layer structure 140B, and thus the above-described difference will be mainly described.

Referring to FIG. 3, the dielectric layer structure 140B may include a first dielectric layer 142, a second dielectric layer 144, a third dielectric layer 146, and a fourth dielectric layer 148. The first dielectric layer 142 may be placed on the lower electrode 130 and the second dielectric layer 144 may be placed in contact with the template layer 150, and the third dielectric layer 146 and the fourth dielectric layer 148 may be placed between the first dielectric layer 142 and the second dielectric layer 144. As illustrated in FIG. 3, the dielectric layer structure 140B may have a structure in which a first dielectric layer 142, a third dielectric layer 146, a fourth dielectric layer 148, and a second dielectric layer 144 are sequentially stacked on the lower electrode 130.

The fourth dielectric layer 148 may include a fourth dielectric material and the fourth dielectric material may be substantially the same as the first dielectric material included in the first dielectric layer 142. In example embodiments, the fourth dielectric material may include at least one of zirconium oxide, aluminum oxide, aluminum silicon oxide, titanium oxide, yttrium oxide, scandium oxide, and lanthanide oxide, but is not limited thereto.

In example embodiments, the third dielectric layer 146 may be interposed between the first dielectric layer 142 and the fourth dielectric layer 148 to reduce the surface roughness of the first dielectric layer 142, to improve the interfacial properties between the first dielectric layer 142 and the fourth dielectric layer 148, or to reduce the leakage current through the first dielectric layer 142 and the fourth dielectric layer 148. In an example embodiment, the first dielectric layer 142 may include zirconium oxide (ZrOₓ), the third dielectric layer 146 may include aluminum oxide (AlOₓ) or aluminum zirconium oxide (AlₓZr_{y}O_{z}), and the fourth dielectric layer 148 may include zirconium oxide (ZrOₓ), but is not limited thereto.

According to the semiconductor device 100B described above, the second dielectric layer 144 may be formed of a hafnium oxide having a tetragonal crystal phase by the template layer 150, and thus the dielectric layer structure 140B may have a relatively high total dielectric constant.

FIG. 4 is a cross-sectional view illustrating a semiconductor device 100C according to example embodiments. In FIG. 4, the same reference numerals as in FIGS. 1 to 3 denote the same elements. The semiconductor device 100C may be the same as the semiconductor device 100 described with reference to FIG. 1 except for the configuration of the dielectric layer structure 140C, and thus the above-described difference will be mainly described.

Referring to FIG. 4, the dielectric layer structure 140C may include a first dielectric layer 142, a second dielectric layer 144, a third dielectric layer 146C, and a fourth dielectric layer 148. The first dielectric layer 142 may be placed on the lower electrode 130 and the second dielectric layer 144 may be placed in contact with the template layer 150, and the third dielectric layer 146C and the fourth dielectric layer 148 may be placed between the first dielectric layer 142 and the second dielectric layer 144.

In the example embodiments, the third dielectric layer 146C may include hafnium oxide. In an example embodiment, the dielectric layer structure 140C may have a structure in which a first dielectric layer 142 including zirconium oxide, a third dielectric layer 146C including hafnium oxide, a third dielectric layer 146c including fourth dielectric layer 148, and a second dielectric layer 144 including hafnium oxide are sequentially arranged, but is not limited thereto.

The second dielectric layer 144 and the third dielectric layer 146C may include hafnium oxide having a tetragonal crystal phase. For example, the dielectric layer structure 140C exhibits a peak of 30.48°±0.2° originated from the {101} plane of a tetragonal crystal structure of the second dielectric layer 144 and the third dielectric layer 146C in an X-ray diffraction analysis. The second dielectric layer 144 and the third dielectric layer 146C may be preferentially oriented to have a tetragonal crystal phase by the template layer 150 during the heat treatment process.

According to the semiconductor device 100C described above, the second dielectric layer 144 and the third dielectric layer 146C may be formed of a hafnium oxide having a tetragonal crystal phase by the template layer 150, and thus the dielectric layer structure 140C may have a relatively high total dielectric constant.

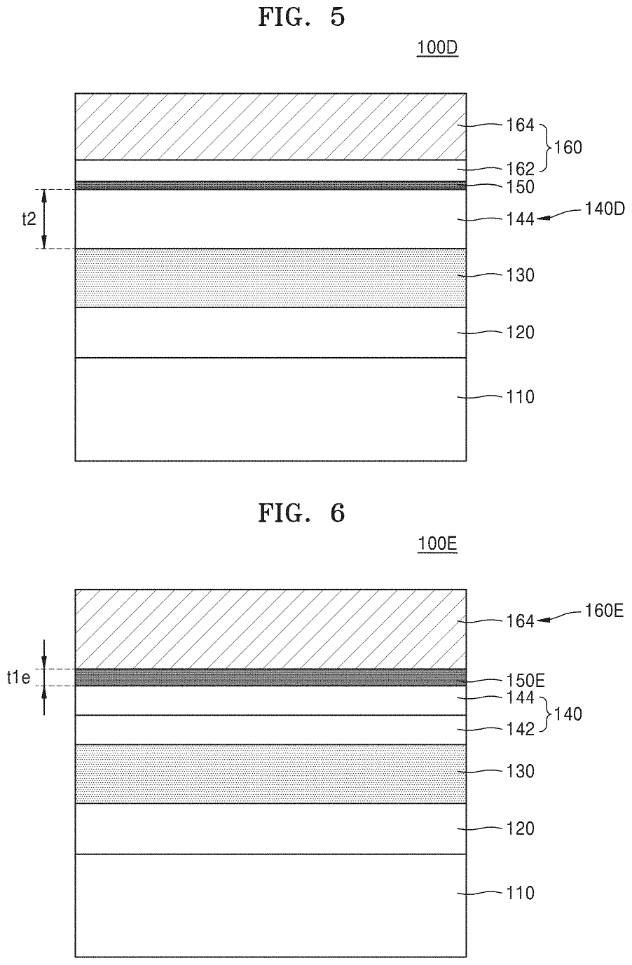

FIG. 5 is a cross-sectional view illustrating a semiconductor device 100D according to example embodiments. In FIG. 5, the same reference numerals as in FIGS. 1 to 4 denote the same elements. The semiconductor device 100D may be the same as the semiconductor device 100 described with reference to FIG. 1 except for the configuration of the dielectric layer structure 140D, and thus the above-described difference will be mainly described.

Referring to FIG. 5, the dielectric layer structure 140D may be formed as a single layer of the second dielectric layer 144. The second dielectric layer 144 may be placed between the lower electrode 130 and the template layer 150 and may contact both the lower electrode 130 and the template layer 150.

In example embodiments, the second dielectric layer 144 may include hafnium oxide having a tetragonal crystal phase and the second dielectric layer 144 may have a second thickness t2 of about 30 Å to about 100 Å. In general, when the dielectric layer includes hafnium oxide, the dielectric layer is likely to have a monoclinic crystal phase having a relatively small dielectric constant. Also, as the thickness of the dielectric layer becomes thicker, the dielectric layer is likely to crystallize into a monoclinic crystal phase having a relatively small dielectric constant. However, due to the template layer 150, the second dielectric layer 144 may have a tetragonal crystal phase even at a relatively large second thickness t2, and thus the dielectric layer structure 140D may have a relatively high total dielectric constant.

FIG. 6 is a cross-sectional view illustrating a semiconductor device 100E according to example embodiments. In FIG. 6, the same reference numerals as in FIGS. 1 to 5 denote the same elements. A semiconductor device 100E may be the same as the semiconductor device 100 described with reference to FIG. 1 except for the configuration of an upper electrode structure 160E, and thus the above-described difference will be mainly described.

Referring to FIG. 6, the upper electrode structure 160E may include only the second upper electrode 164, and the second upper electrode 164 may be placed directly above a template layer 150E. The template layer 150E may include niobium oxide (NbOₓ, 0.5≤x≤2.5) and may have a first thickness t1e of about 1 to 10 angstroms (Å), but is not limited thereto.

In an example manufacturing process, a template layer 150E including niobium oxide may be formed on the dielectric layer structure 140 by an atomic layer deposition (ALD) process or a chemical vapor deposition (CVD) process, and the second upper electrode 164 may be formed on the template layer 150E by an ALD process or a CVD process.

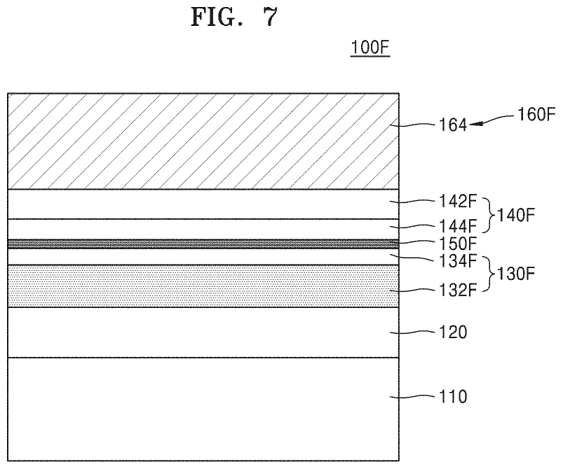

FIG. 7 is a cross-sectional view illustrating a semiconductor device 100F according to example embodiments. In FIG. 7, the same reference numerals as in FIGS. 1 to 6 denote the same elements. The semiconductor device 100F may be the same as the semiconductor device 100E described with reference to FIG. 5 except that the template layer 150F is placed between the dielectric layer structure 140F and the lower electrode structure 130F, and thus the differences described above will be mainly described.

Referring to FIG. 7, the lower electrode structure 130F may include a first lower electrode 132F and a second lower electrode 134F which are sequentially stacked on the interlayer insulating film 120. A template layer 150F may be placed on the second lower electrode 134F and a dielectric layer structure 140F may be placed on the template layer 150F and the dielectric layer structure 140F may include a second dielectric layer 144F and a first dielectric layer 142F that are sequentially stacked on the template layer 150F. The upper electrode structure 160F may include only the second upper electrode 164 and the upper electrode structure 160F may be placed on the first dielectric layer 142F.

In example embodiments, the first lower electrode 132F may include at least one of a metal such as a doped silicon, a doped silicon germanium, ruthenium (Ru), titanium (Ti), tantalum (Ta), niobium (Nb), iridium (Jr), molybdenum (Mo) and tungsten (W), a conductive metal nitride such as titanium nitride (TiN), tantalum nitride (TaN), niobium nitride (NbN), molybdenum nitride (MoN), tungsten nitride (WN), and a conductive metal oxide such as iridium oxide. The second lower electrode 134F may include niobium nitride (NbN_{y}, 0.5≤y≤1.0).

In the example embodiments, the first dielectric layer 142F may include a first dielectric material, which may include a high-k material having a higher dielectric constant than silicon oxide. For example, the first dielectric material may include at least one of zirconium oxide, aluminum oxide, aluminum silicon oxide, titanium oxide, yttrium oxide, scandium oxide, and lanthanide oxide, but is not limited thereto. The second dielectric layer 144F may include hafnium oxide having a tetragonal crystal phase.

As illustrated in FIG. 7, a template layer 150F may be interposed between the second lower electrode 134F and the second dielectric layer 144F to contact the second lower electrode 134F and the second dielectric layer 144F. In an example manufacturing process, in a process for forming a second lower electrode 134F including niobium nitride and forming a second dielectric layer 144F on the second lower electrode 134F, a portion of the second lower electrode 134F from a top surface of the second lower electrode 134F exposed to process atmosphere may be oxidized to form the template layer 150F including niobium oxide. In another example manufacturing process, a second lower electrode 134F including niobium nitride may be formed, and then a template layer 150F including niobium oxide may be formed by an ALD process or a CVD process. During the subsequent heat treatment process, the second dielectric layer 144F may be crystallized by the template layer 150F to have a tetragonal crystal phase.

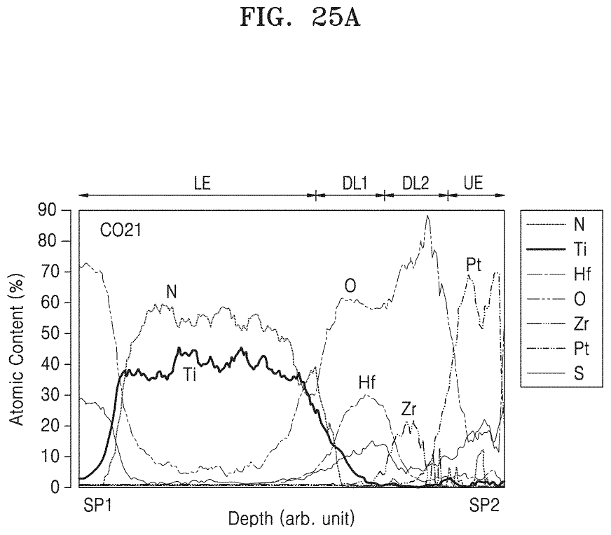

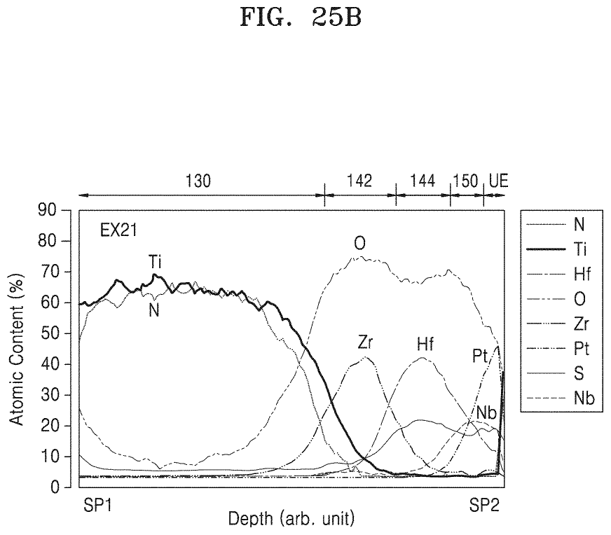

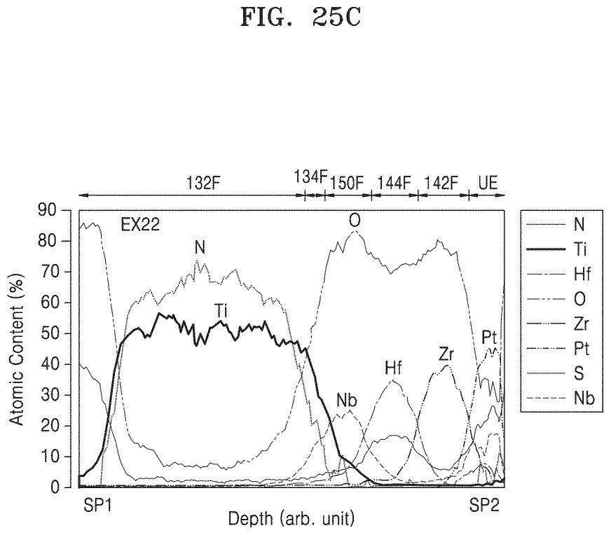

Hereinafter, an amount of elements included in the semiconductor device according to example embodiments and an X-ray diffraction analysis graph of the semiconductor device according to experimental examples and a comparative example will be described with reference to FIGS. 25a to 25c and FIG. 26.

FIGS. 25a to 25c illustrate an energy-dispersive X-ray spectroscopy (EDX) analysis graph with respect to a semiconductor device according to example embodiments. FIGS. 25a to 25c illustrate an amount of elements included in the semiconductor device along a scan line from a first scan point SP1 (see FIG. 1) in the lower electrode 130 to a second scan point SP2 (see FIG. 1) in the second upper electrode 164 with respect to each of a semiconductor device CO21 according to a comparative example, a semiconductor device EX21 according to a first experimental example and a semiconductor device EX22 according to a second experimental example.

To form the semiconductor device CO21 according to the comparative example illustrated in FIG. 25a, a first dielectric layer DL1 including hafnium oxide was formed on a lower base electrode LE including titanium nitride, a second dielectric layer DL2 including zirconium oxide was formed on the first dielectric layer DL1, and an upper base electrode UE including platinum was formed on the second dielectric layer DL2.

The semiconductor device EX21 according to experimental example 1 illustrated in FIG. 25B was formed in a structure similar to the semiconductor device 100 described with reference to FIG. 1. For example, the semiconductor device EX21 according to experimental example 1 was formed to include a lower electrode 130 including titanium nitride, a first dielectric layer 142 including zirconium oxide, a second dielectric layer 144 including hafnium oxide, a template layer 150 including an niobium oxide, and an upper base electrode UE including platinum.

The semiconductor device EX22 according to experimental example 2 illustrated in FIG. 25c was formed in a structure similar to the semiconductor device 100F described with reference to FIG. 7. For example, the semiconductor device EX22 according to experimental example 2 was formed to include a first lower electrode 132F including titanium nitride, a second lower electrode 134F including niobium nitride, a template layer 150F including an niobium oxide, a second dielectric layer 144F including hafnium oxide, a first dielectric layer 142F including zirconium oxide, and an upper base electrode UE including platinum.

Referring to FIGS. 25a to 25c, it may be confirmed that the template layer 150 placed on the second dielectric layer 144 in the semiconductor device EX21 according to Experimental Example 1 has a composition of niobium oxide. In addition, although not illustrated, it may be confirmed that the template layer 150 is formed to have a uniform thickness (e.g., a uniform thickness of 10 Å or less) over the entire area of the second dielectric layer 144. In the semiconductor device EX22 according to experimental example 2, the template layer 150F placed on the second lower electrode 134F may have a composition of niobium oxide, and it may be seen that the second dielectric layer 144F placed on the template layer 150F has a composition of hafnium oxide. In addition, although not illustrated, it may be confirmed that the template layer 150F is formed to have a uniform thickness (e.g., a uniform thickness of 10 Å or less) over the entire area of the second lower electrode 134F. In the semiconductor device CO21 according to the comparative example, it may be confirmed that the first dielectric layer DL1 placed on the lower base electrode LE has a composition of hafnium oxide.

FIG. 26 illustrates an X-ray diffraction analysis graph of a semiconductor device according to a comparative examples and an experimental example.

Referring to FIG. 26, in the semiconductor device (CO21) according to the comparative example, a first peak (▴) originated from the (−111) plane of the monoclinic crystal phase at about 28.30° is observed, while a second peak (●) from the (101) plane of the tetragonal crystal phase at about 30.48° is observed with a relatively small intensity. On the other hand, in the semiconductor device EX21 according to experimental example 1, the first peak (▴) from the (−111) plane of the monoclinic crystal phase at about 28.30° is observed with relatively small intensity, while the second peak (●) due to the (101) plane of the tetragonal crystal phase at about 30.48° is observed with a relatively large intensity. In addition, in the semiconductor device EX21 according to experimental example 2, the first peak (▴) from the (−111) plane of the monoclinic crystal phase at about 28.30° is hardly observed or is observed with a slight intensity, while the second peak (●) from the (101) plane of the tetragonal crystal phase at about 30.48° is observed with a relatively large intensity. That is, it may be confirmed that the hafnium oxide on the titanium nitride is preferentially oriented to have the monoclinic crystal phase in the semiconductor device CO21 according to the comparative example, while the hafnium oxide in contact with the template layer containing niobium oxide is preferentially oriented to have a tetragonal crystal phase in the semiconductor devices EX21 and EX22 according to experimental examples 1 and 2. This may be more clearly seen with reference to Table 1 below, which measures the intensity ratio between the first peak (▴) and the second peak (●).

TABLE 1

| | First peak/Second peak |
|---|---|
| Kinds | (m-phase/t-phase)(arb. unit) |
| Comparative Example (CO21) | 0.690 |
| First experimental example (EX21) | 0.230 |
| Second experimental example (EX22) | 0.114 |

Referring to Table 1, in the semiconductor device CO21 according to the comparative example, the ratio of the intensity of the first peak (▴) of the monoclinic crystal phase (m-phase) to the intensity of the second peak (●) of the tetragonal crystal phase (t-phase) is 0.690, while the ratio of the intensity of the first peak (▴) of the monoclinic crystal phase (m-phase) to the intensity of the second peak (●) of the tetragonal crystal phase is 0.230 in the semiconductor device EX21 according to experimental example 1. That is, the intensity of the second peak (●) of the tetragonal crystal phase (t-phase) in the semiconductor device EX21 according to experimental example 1 is significantly greater than the intensity of the second peak (●) of the tetragonal crystal phase (t-phase) in the semiconductor device CO21 according to the comparative example. In addition, in the semiconductor device EX22 according to experimental example 2, the ratio of the intensity of the first peak (▴) of the monoclinic crystal phase (m-phase) to the intensity of the second peak (●) of the tetragonal crystal phase (t-phase) is 0.114. That is, the intensity of the second peak (D) of the tetragonal crystal phase (t-phase) in the semiconductor device EX22 according to experimental example 2 is significantly greater than the intensity of the second peak (●) of the tetragonal crystal phase (t-phase) in the semiconductor device CO21. Also, the intensity of the second peak (●) of the tetragonal crystal phase (t-phase) in the semiconductor device EX22 according to experimental example 2 is greater than the intensity of the second peak (●) of the tetragonal crystal phase (t-phase) in the semiconductor device EX21.

That is, since the interfacial energy between the niobium oxide surface and the hafnium oxide surface of the tetragonal structure is smaller than the interfacial energy between the niobium oxide surface and the hafnium oxide of the monoclinic structure, it may be assumed that the hafnium oxide on the surface of the niobium oxide is crystallized to preferentially orient or predominantly orient the hafnium oxide in the tetragonal crystal phase.

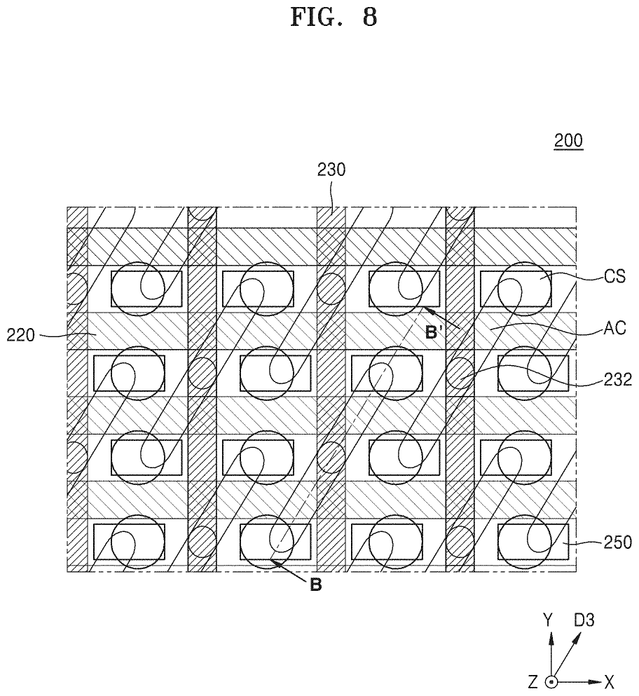

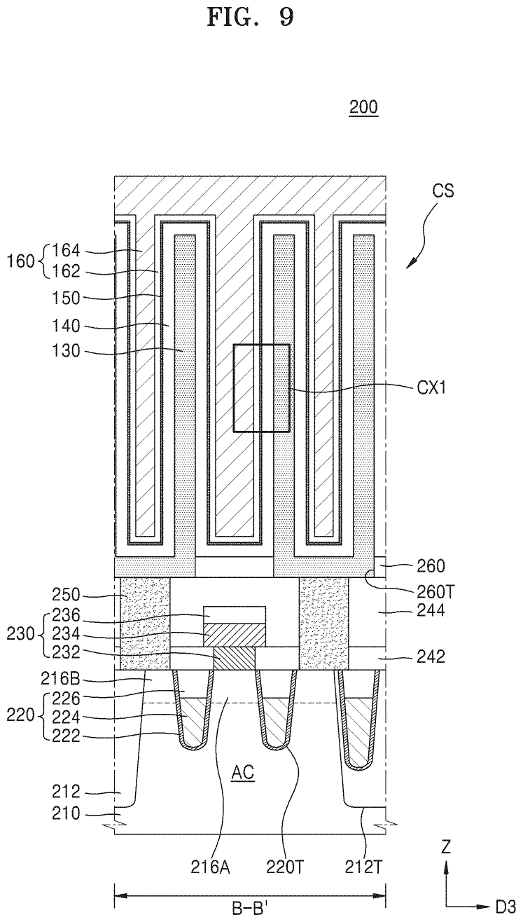

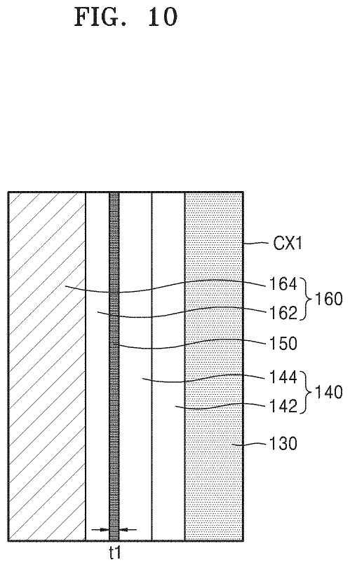

FIG. 8 is a layout diagram illustrating a semiconductor device 200 according to example embodiments. FIG. 9 is a cross-sectional view taken along line B-B′ of FIG. 8, and FIG. 10 is an enlarged view of a portion CX1 of FIG. 9. In FIGS. 8 to 10, the same reference numerals as in FIGS. 1 to 7 denote the same components.

Referring to FIGS. 8 to 10, a substrate 210 may have an active region AC defined by a device isolation layer 212. In example embodiments, the substrate 210 may include a semiconductor material such as Si, Ge, or SiGe, SiC, GaAs, InAs, or InP. In example embodiments, the substrate 210 may include a conductive region, for example, a well doped with an impurity, or a structure doped with an impurity.

The device isolation layer 212 may have a shallow trench isolation (STI) structure. For example, the device isolation layer 212 may include an insulating material filling the device isolation trench 212T formed in the substrate 210. The insulating material may include fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate, or tonen silazene (TOSZ), but is not limited thereto.

An active region AC may have a relatively long island shape having each of a short axis and a long axis. In an example embodiment, as described with reference to FIG. 8, the long axis of the active region AC may be arranged along a direction D3 parallel to a top surface of the substrate 110. In example embodiments, the active region AC may be doped with P-type or N-type impurities.

The substrate 210 may further include a gate line trench 220T extending along an X direction parallel to a top surface of the substrate 210. The gate line trench 220T may intersect the active region AC and may be formed at a certain depth from the top surface of the substrate 210. A portion of the gate line trench 220T may extend into the device isolation layer 212 and a portion of the gate line trench 220T formed in the device isolation layer 212 may include a bottom surface located at a lower level than a portion of the gate line trench 220T formed in the active region AC.

A first source/drain region 216A and a second source/drain region 216B may be placed in an upper portion of the active region AC located on both sides of the gate line trench 220T. Each of the first source/drain region 216A and the second source/drain region 216B may be an impurity region doped with an impurity having a conductivity type different from an impurity doped in the active region AC. The first source/drain region 216A and the second source/drain region 216B may be doped with N-type or P-type impurities.

A gate structure 220 may be formed in the gate line trench 220T. The gate structure 220 may include a gate insulating layer 222, a gate electrode 224, and a gate capping layer 226 sequentially formed on an inner wall of the gate line trench 220T.

The gate insulating layer 222 may be conformally formed on the inner wall of the gate line trench 220T to a certain thickness. The gate insulating layer 222 may be at least one selected from the group consisting of silicon oxide, silicon nitride, silicon oxynitride, oxide/nitride/oxide (ONO), or a high dielectric material having a dielectric constant higher than silicon oxide. For example, the gate insulating layer 222 may have a dielectric constant of about 10 to 25. In some embodiments, the gate insulating layer 222 may be made of HfO₂, ZrO₂, Al₂O₃, HfAlO₃, Ta₂O₃, TiO₂, or a combination thereof, but is not limited to the above examples.

The gate electrode 224 may be formed on the gate insulating layer 222 to fill the gate line trench 220T from the bottom of the gate line trench 220T to a certain height. The gate electrode 224 may include a work function control layer (not illustrated) placed on the gate insulating layer 222 and a buried metal layer (not illustrated) filling the bottom of the gate line trench 220T on the work function control layer. For example, the work function control layer may include a metal, a metal nitride or a metal carbide such as Ti, TiN, TiAlN, TiAlC, TiAlCN, TiSiCN, Ta, TaN, TaAlN, TaAlCN, TaSiCN, and the buried metal layer may include at least one of W, WN, TiN, and TaN, but is not limited thereto.

The gate capping layer 226 may fill the remaining portion of the gate line trench 220T on the gate electrode 224. For example, the gate capping layer 226 may include at least one of silicon oxide, silicon oxynitride, and silicon nitride.

A bit line structure 230 may be formed on the first source/drain region 216A, and the bit line structure 230 may extend parallel to the top surface of the substrate 210 and may extend along the Y direction perpendicular to the X direction. The bit line structure 230 may include a bit line contact 232, a bit line 234 and a bit line capping layer 236 that are sequentially stacked on a substrate 210. For example, the bit line contact 232 may include polysilicon and the bit line 234 may include a metallic material. The bit line capping layer 236 may include an insulating material such as silicon nitride or silicon oxynitride. FIG. 9 may be illustratively shown to be formed with the bit line contact 232 having a bottom surface at the same level as the top surface of the substrate 210. In contrast, a recess (not illustrated) may be formed at a certain depth from the top surface of the substrate 210 and the bit line contact 232 may extend to an interior of the recess such that the bottom surface of the bit line contact 232 is formed at a lower level than the top surface of the substrate 210.

Alternatively, a bit line intermediate layer (not illustrated) may be interposed between the bit line contact 232 and the bit line 234. The bit line intermediate layer may include a metal silicide such as tungsten silicide, or a metal nitride such as tungsten nitride. A bit line spacer (not illustrated) may be further formed on sidewalls of the bit line structure 230. The bit line spacers may have a single layer structure or a multilayer structure composed of an insulating material such as silicon oxide, silicon oxynitride, or silicon nitride. In addition, the bit line spacers may further include an air space (not illustrated).

A first interlayer insulating film 242 may be formed on the substrate 210 and the bit line contact 232 may be connected to the first source/drain region 216A through the first interlayer insulating film 242. The bit line 234 and a bit line capping layer 236 may be placed on the first interlayer insulating film 242. A second interlayer insulating film 244 may be placed on the first interlayer insulating film 242 to cover side surfaces and a top surface of the bit line 234 and the bit line capping layer 236.

The contact structure 250 may be placed on the second source/drain region 216B. The first and second interlayer insulating films 242 and 244 may surround the sidewalls of the contact structure 250. In example embodiments, the contact structure 250 may include a lower contact pattern (not illustrated), a metal silicide layer (not illustrated), and an upper contact pattern (not illustrated) that are sequentially stacked on the substrate 210, and a barrier layer (not illustrated) surrounding side surfaces and bottom surfaces of the upper contact pattern. In example embodiments, the lower contact pattern may include polysilicon, and the upper contact pattern may include a metallic material. The barrier layer may include a metal nitride having conductivity.

A capacitor structure CS may be placed on the second interlayer insulating film 244. The capacitor structure CS may include a lower electrode 130 that is in electrical contact with the contact structure 250, a dielectric layer structure 140 that conformally covers the lower electrode 130, a template layer 150 on the dielectric layer structure 140, and/or an upper electrode structure 160 on the template layer 150. Meanwhile, an etch stop layer 260 having an opening 260T may be formed on the second interlayer insulating film 244 and a bottom portion of the lower electrode 130 may be placed in the opening 260T of the etch stop layer 260.

FIG. 8 is illustrated by way of example capacitor structures CS being repeatedly arranged along the X and Y directions on a contact structure 250 that is repeatedly arranged along the X and Y directions. However, unlike that illustrated in FIG. 8, the capacitor structure CS may be arranged in a hexagonal shape, for example, a honeycomb structure, on a contact structure 250 that is repeatedly arranged along the X and Y directions, a landing pad (not illustrated) may be further formed between the contact structure 250 and the capacitor structure CS.

The lower electrode 130 may be formed in a cylindrical shape or a cup shape with the lower portion closed on the contact structure 250. The description of the lower electrode 130 may be referred to the contents described with reference to FIG. 1.

The dielectric layer structure 140 may be placed on the lower electrode 130 and the etch stop layer 260. The dielectric layer structure 140 may have a stacked structure of the first dielectric layer 142 and the second dielectric layer 144. The dielectric layer structure 140 may include a first dielectric layer 142 that is conformally placed on the lower electrode 130 and the etch stop layer 260 and a second dielectric layer 144 that is placed on the first dielectric layer 142, and the second dielectric layer 144 may include hafnium oxide having a tetragonal crystal phase. Description of the dielectric layer structure 140 may refer to the contents described above with reference to FIG. 1.

FIGS. 8 to 10 illustrate an example in which the dielectric layer structure 140 has a stacked structure of the first dielectric layer 142 and the second dielectric layer 144. However, the technical idea of the inventive concepts is not limited thereto, and the dielectric layer structures 140A, 140B, 140C, and 140D described with reference to FIGS. 2 to 5 may be placed on the lower electrode 130 instead of the dielectric layer structure 140.

A template layer 150 may be placed on the dielectric layer structure 140. The template layer 150 may be conformally placed on the dielectric layer structure 140 and may cover the lower electrode 130 with the dielectric layer structure 140 therebetween. In example embodiments, the template layer 150 may be placed in contact with an entire top surface of the second dielectric layer 144. For example, the entire top surface of the second dielectric layer 144 may refer to as an entire surface of a portion of the second dielectric layer 144 surrounding an outer wall of the lower electrode 130, and an entire surface of a portion of the second dielectric layer 144 surrounding an inner wall of the lower electrode 130, an entire surface of the portion of the second dielectric layer 144 placed on the uppermost surface of the lower electrode 130, and an entire surface of the portion of the second dielectric layer 144 placed on the bottom portion of the lower electrode 130. The template layer 150 may include niobium oxide and may serve as a crystallization-inducing layer that may preferentially orient the second dielectric layer 144 to have a tetragonal crystal phase. In addition, the template layer 150 may serve as a protective layer that reduces or prevents the dielectric layer structure 140 from being damaged or penetration of materials such as reactants into the dielectric layer structure 140 during the process of forming the upper electrode structure 160 (or the process of forming the second upper electrode 164). A description of the template layer 150 may be the same as described with reference to FIG. 1.

The upper electrode structure 160 may be placed on the template layer 150. The upper electrode structure 160 may include a first upper electrode 162 in contact with the entire top surface of the template layer 150 and a second upper electrode 164 on the first upper electrode 162. The first upper electrode 162 may include niobium nitride. A description of the upper electrode structure 160 may refer to the contents described with reference to FIG.

According to the semiconductor device 200 described above, the second dielectric layer 144 may be formed of a hafnium oxide having a tetragonal crystal phase by the template layer 150, and thus the dielectric layer structure 140 may have a relatively high total dielectric constant. Thus, the semiconductor device 200 may have high capacitance and excellent electrical characteristics.

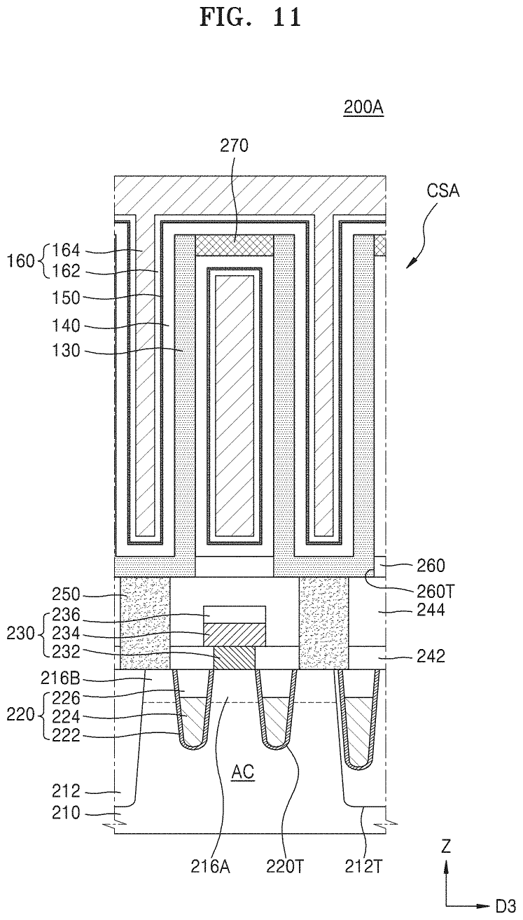

FIG. 11 is a cross-sectional view illustrating a semiconductor device 200A according to example embodiments. FIG. 11 is a cross-sectional view corresponding to a cross section taken along the line B-B′ in FIG. 8. In FIG. 11, the same reference numerals as in FIGS. 1 to 10 denote the same components.

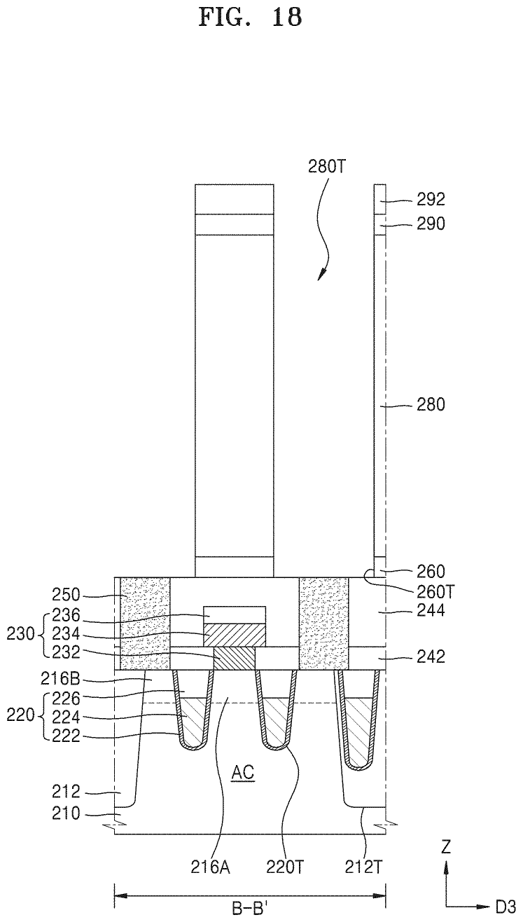

Referring to FIG. 11, the capacitor structure CSA may further include a support portion 270 placed between the lower electrode 130 and the lower electrode 130 adjacent thereto. The support portion 270 may reduce or prevent the lower electrode 130 from falling or tilting in the process of removing the mold layer 280 (see FIG. 18) and/or the process of forming the dielectric layer structure 140.

As illustrated by way of an example in FIG. 11, the support portion 270 may have a top surface positioned in the same plane as the uppermost surface of the lower electrode 130, but is not limited thereto. Unlike the one illustrated in FIG. 11, a plurality of support portions 270 positioned at different vertical levels may be placed on the sidewalls of the lower electrode 130. In addition. The support portion 270 may include silicon nitride, silicon oxide, silicon oxynitride, metal oxide, or the like.

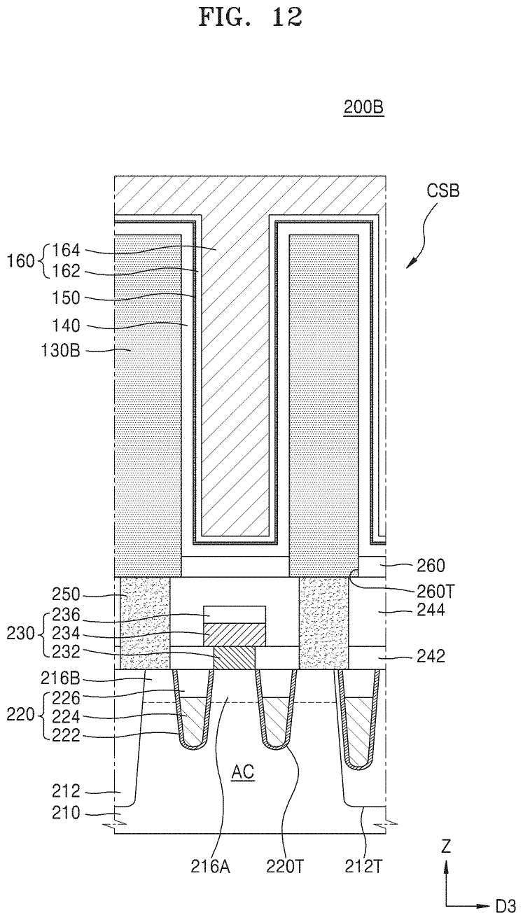

FIG. 12 is a cross-sectional view illustrating a semiconductor device 200B according to example embodiments. FIG. 12 is a cross-sectional view corresponding to a cross section taken along the line B-B′ in FIG. 8. In FIG. 12, the same reference numerals as in FIGS. 1 to 11 denote the same components.

Referring to FIG. 12, the capacitor structure CSB may include a lower electrode 130B. A bottom portion of the lower electrode 130B may be placed in the opening 260T of the etch stop layer 260 and the lower electrode 130B is formed of a cylinder, a square column, or polygonal column extending along the vertical direction (e.g., Z direction). The dielectric layer structure 140 may be conformally placed on the lower electrode 130B and the etch stop layer 260. Although not illustrated, a supporting portion (not illustrated) may be further formed on the sidewalls of the lower electrode 130B to reduce or prevent the lower electrode 130B from tilting or falling down.

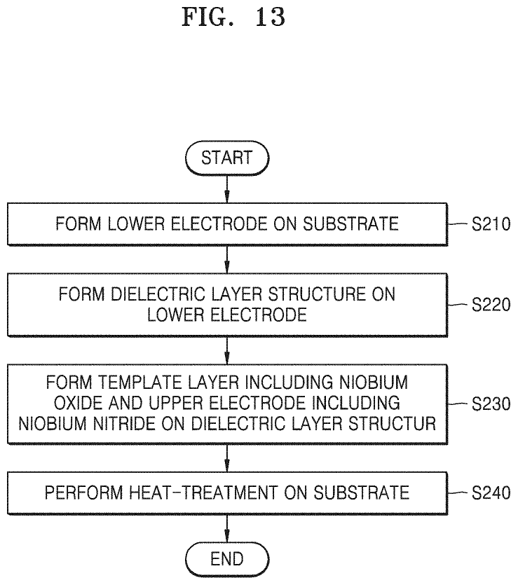

FIG. 13 is a flowchart schematically showing a method of manufacturing a semiconductor device according to example embodiments. FIG. 13 may be a method of manufacturing the semiconductor devices 100, 100A, 100B, 100C, 100D and 100E described with reference to FIGS. 1 to 6.

Referring to FIG. 13, a lower electrode may be formed on a substrate (operation S210).

An interlayer insulating film or another substructure may be further formed on the substrate before the lower electrode may be formed. The lower electrode may be formed by a chemical vapor deposition (CVD) process, a metal organic chemical vapor deposition (MOCVD) process, an atomic layer deposition (ALD) process, or a metal organic ALD (MOALD) process, but is not limited thereto.

Afterwards, a dielectric layer structure may be formed on the lower electrode (operation S220).

The dielectric layer structure may be formed as a stacked structure including a first dielectric layer and a second dielectric layer. For example, the first dielectric layer may be formed using a first dielectric material by a CVD process, an MOCVD process, an ALD process, an MOALD process, or the like, and the second dielectric layer may include a CVD process, an MOCVD process, an ALD process, an MOLD process, or the like, by using a second dielectric material different from the first dielectric material. The second dielectric material may include hafnium oxide.

Afterwards, a template layer including niobium oxide and an upper electrode including niobium nitride may be formed on the dielectric layer structure (operation S230).

The upper electrode may be formed on the dielectric layer structure using niobium nitride by a CVD process, an MOCVD process, an ALD process, an MOALD process, or the like. For example, when an ALD process or an MOALD process is performed to form the upper electrode, a precursor including niobium (Nb) and a reactant material including nitrogen (N) are alternately and repeatedly supplied.

In the process for forming the upper electrode, the niobium-including precursor may be oxidized to form a template layer having a relatively thin first thickness t1 (see FIG. 1).

Alternatively, a portion of the upper electrode that is in contact with or placed adjacent to the dielectric layer structure may be oxidized. In that case, the template layer including niobium oxide may be formed at the interface of the upper electrode and the dielectric layer structure to have a first thickness t1 that is relatively thin.

Afterwards, the substrate may be heat-treated (operation S240).

The step of heat-treating the substrate may be performed at a temperature of about 200° C. to 500° C. for several minutes to several hours. The template layer placed on the entire top surface of the second dielectric layer in the heat treatment step may serve as a crystallization-inducing layer for preferential orientation of the second dielectric layer and the second dielectric layer may be crystallized to have a tetragonal crystal phase.

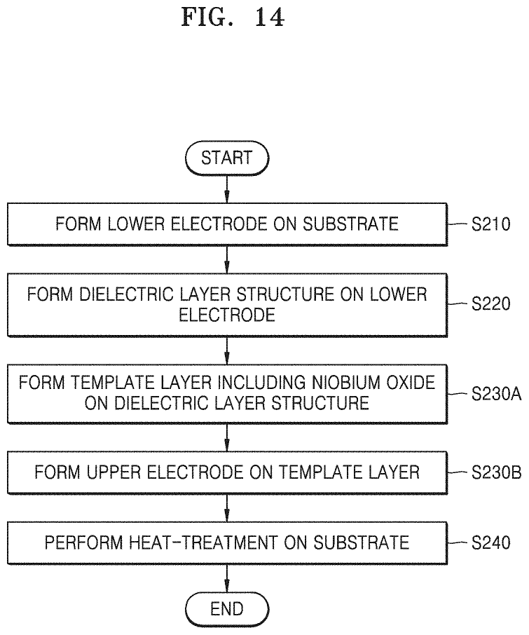

FIG. 14 is a flowchart schematically showing a method of manufacturing a semiconductor device according to example embodiments. FIG. 14 may be a manufacturing method of the semiconductor devices 100, 100A, 100B, 100C, 100D and 100E described with reference to FIGS. 1 to 6.

Referring to FIG. 14, a lower electrode may be formed on a substrate (operation S210).

Afterwards, a dielectric layer structure may be formed on the lower electrode (operation S220).

Thereafter, a template layer including niobium oxide may be formed on the dielectric layer structure (operation S230A).

The template layer may be formed on the dielectric layer structure using a niobium oxide by a CVD process, an MOCVD process, an ALD process, an MOALD process, or the like. For example, when an ALD process or an MOALD process is performed to form the template layer, a precursor including niobium (Nb) and a reactant including oxygen (O) are alternately and repeatedly supplied on the dielectric layer structure.

Afterwards, an upper electrode may be formed on the template layer (operation S230B).

In example embodiments, the upper electrode may include niobium nitride. When an ALD process or an MOALD process is performed to form the upper electrode, a precursor including niobium (Nb) and a reactant including nitrogen (N) may be alternately and repeatedly supplied on the dielectric layer structure.

In other embodiments, the upper electrode may include at least one selected from a metal such as doped silicon, doped silicon germanium, ruthenium (Ru), titanium (Ti), tantalum (Ta), niobium (Nb), iridium (Jr), molybdenum (Mo), tungsten (W), a conductive metal nitride such as titanium nitride (TiN), tantalum nitride (TaN), niobium nitride (NbN), molybdenum nitride (MoN), tungsten nitride (WN), and conductive metal oxide such as iridium oxide.

Afterwards, the substrate may be heat-treated (operation S240).

The template layer placed on the entire top surface of the second dielectric layer in the heat treatment step may serve as a crystallization-inducing layer for preferential orientation of the second dielectric layer and the second dielectric layer may be crystallized to have a tetragonal crystal phase.

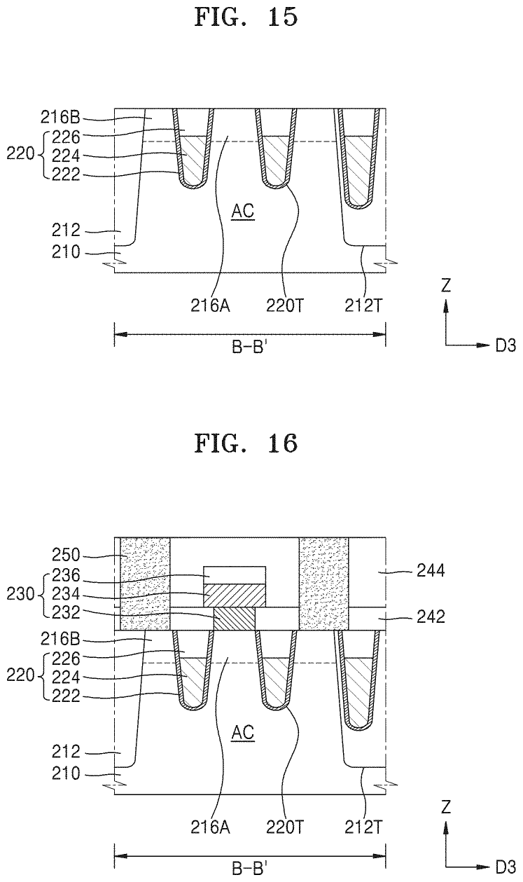

FIGS. 15 to 24 are cross-sectional views illustrating a manufacturing method of the semiconductor device 200 based on a process order according to example embodiments.

Referring to FIG. 15, a device isolation trench 212T may be formed on a substrate 210, and a device isolation layer 212 may be formed in a device isolation trench 212T. The active region AC may be defined on the substrate 210 by the device isolation layer 212.

Afterwards, a first mask (not illustrated) may be formed on the substrate 210, and the gate line trench 220T may be formed on the substrate 210 using a first mask as an etching mask. The gate line trench 220T may extend parallel to each another and may have a line shape across the active region AC.

Thereafter, the gate insulating layer 222 may be formed on the inner wall of the gate line trench 220T. After a gate conductive layer (not illustrated) filling the inside of the gate line trench 220T is formed on the gate insulating layer 222, the gate conductive layer may be removed by a certain height by an etch-back process to form the gate electrode 224.

Afterwards, an insulating material may be formed to fill the remaining portion of the gate line trench 220T and the gate capping layer 226 may be formed on the inner wall of the gate line trench 220T by planarizing the insulating material until the top surface of the substrate 210. Thereafter, the first mask may be removed.

Afterwards, impurity ions may be implanted into the substrate 210 on both sides of the gate structure 220 to form the first and second source/drain regions 216A and 216B. Alternatively, after the device isolation layer 212 is formed, impurity ions may be implanted into the substrate 210 to form the first and second source/drain regions 216A and 216B above the active region AC.

Referring to 16, a first interlayer insulating film 242 may be formed on a substrate 210 and an opening (not illustrated) exposing a top surface of the first source/drain region 216A may be formed in the first interlayer insulating film 242. A conductive layer (not illustrated) for filling the opening may be formed on the first interlayer insulating film 242, and the upper side of the conductive layer may be planarized to form a bit line contact 232 electrically connected to the first source/drain region 216A in the opening.

Thereafter, a conductive layer (not illustrated) and an insulating layer (not illustrated) may be sequentially formed on the first interlayer insulating film 242, and the insulating layer and the conductive layer may be patterned to form a bit line capping layer 236 and a bit line 234 extending in the Y direction (see FIG. 8) parallel to the top surface of the substrate 210. Although not illustrated, a bit line spacer (not illustrated) may be further formed on the sidewalls of the bit line 234 and the bit line capping layer 236.

Afterwards, a second interlayer insulating film 244 covering the bit line 234 and the bit line capping layer 236 may be formed on the first interlayer insulating film 242.

Thereafter, an opening (not illustrated) for exposing a top surface of the second source/drain region 216B may be formed in the first and second interlayer insulating films 242 and 244, and the contact structure 250 may be formed in the opening. In example embodiments, the contact structure 250 (not illustrated) may be formed by sequentially forming a lower contact pattern (not illustrated), a metal silicide layer (not illustrated), a barrier layer (not illustrated), and an upper contact pattern inside the opening.

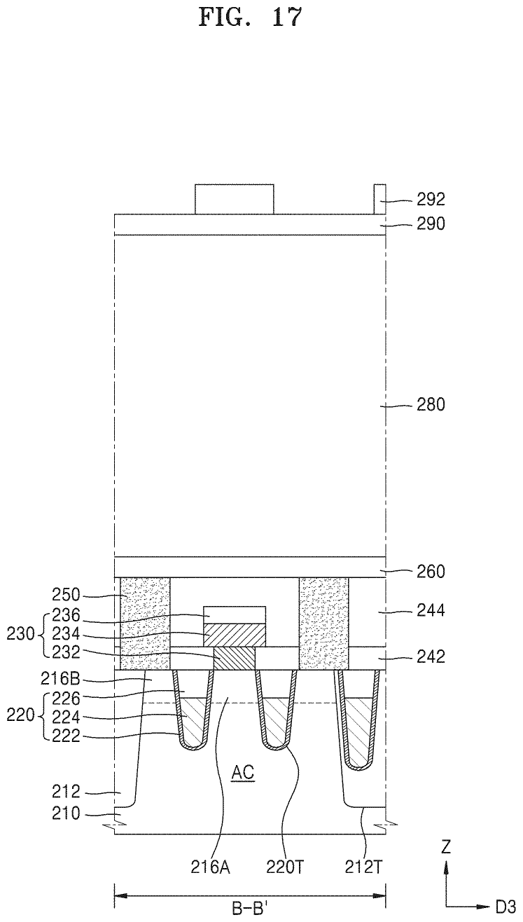

Referring to FIG. 17, an etch stop layer 260, a mold layer 280, and a sacrificial layer 290 may be sequentially formed on the second interlayer insulating film 244 and the contact structure 250.

In the example embodiments, the mold layer 280 and the etch stop layer 260 may include materials having etch selectivity relative to each other. For example, when the mold layer 280 includes silicon oxide, the etch stop layer 260 may include silicon nitride. In the example embodiments, the mold layer 280 may be formed of a plurality of layers using materials having different etching rates from each other. In addition, the mold layer 280 and the sacrificial layer 290 may also include materials having etch selectivity relative to each other.

Thereafter, the mask pattern 292 may be formed on the sacrificial layer 290.

Referring to FIG. 18, the sacrificial layer 290 and the mold layer 280 may be sequentially etched using the mask pattern 292 to form the opening 280T.

Afterwards, the etch stop layer 260 exposed at the bottom of the opening 280T may be removed to form the opening 260T. A top surface of the contact structure 250 may be exposed by the opening 280T and the opening 260T.

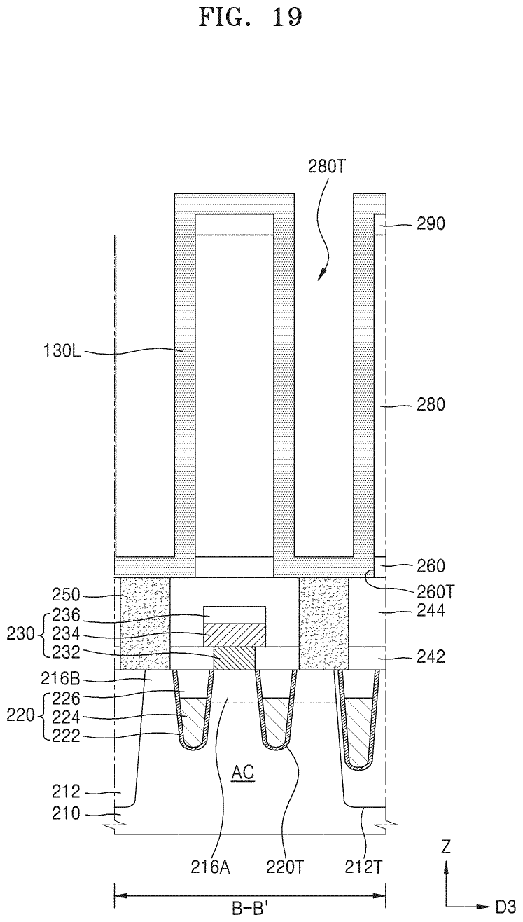

Referring to FIG. 19, the mask pattern 292 may be removed.

Thereafter, a preliminary lower electrode layer 130L may be formed to conformally cover the inner walls of the openings 150T and 210H on the etch stop layer 260, the mold layer 280, and the sacrificial layer 290.

For example, the process of forming the preliminary lower electrode layer 130L may be a CVD process, an MOCVD process, an ALD process, or an MOALD process.

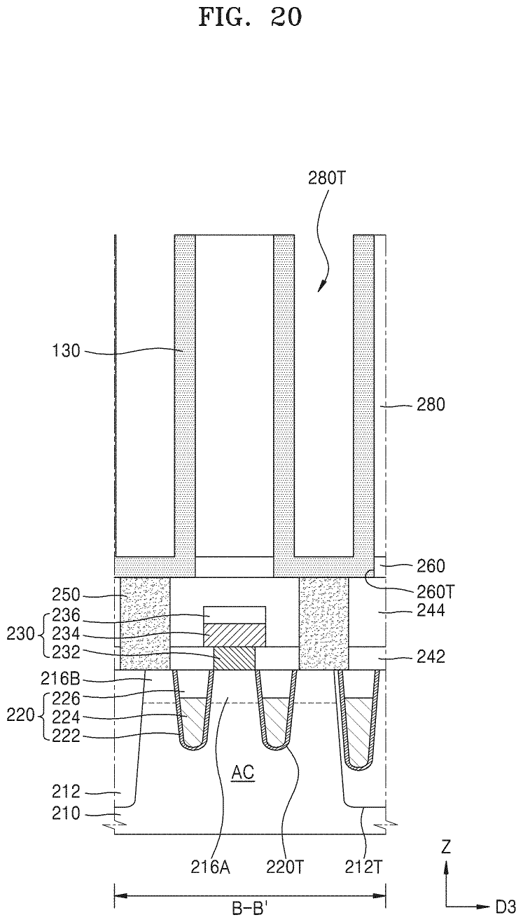

Referring to FIG. 20, the lower electrode 130 is formed by removing a portion of the preliminary lower electrode layer 130L (see FIG. 19) located on a top surface of the mold layer 280 and the sacrificial layer 290 by the etch-back process.

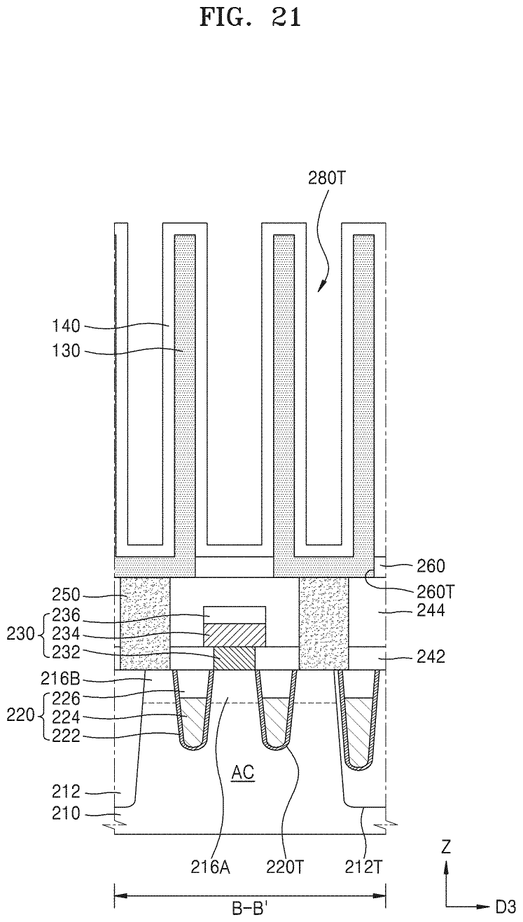

Referring to FIG. 21, the mold layer 280 (see FIG. 20) may be removed. In the process of removing the mold layer 280, the etch stop layer 260 may remain without being removed. The lower electrode 130 may be placed on the contact structure 250 and the bottom portion may be formed in a closed cylinder shape.

Afterwards, the dielectric layer structure 140 may be formed by sequentially forming the first dielectric layer 142 (see FIG. 10) and the second dielectric layer 144 (see FIG. 10) on the lower electrode 130 and the etch stop layer 260. The first dielectric layer 142 may be formed using a first dielectric material by a CVD process, an MOCVD process, an ALD process, an MOALD process, or the like. The second dielectric layer 144 may be formed using a second dielectric material by a CVD process, an MOCVD process, an ALD process, an MOALD process, or the like, and the second dielectric material may include hafnium oxide.

In other embodiments, a third dielectric layer 146 may be formed prior to forming the second dielectric layer 144, or a third dielectric layer 146 and a fourth dielectric layer 148 may be sequentially formed. In this case, the semiconductor devices 100A, 100B, and 100C including the dielectric layer structures 140A, 140B, and 140C described with reference to FIGS. 2 to 4 may be formed.

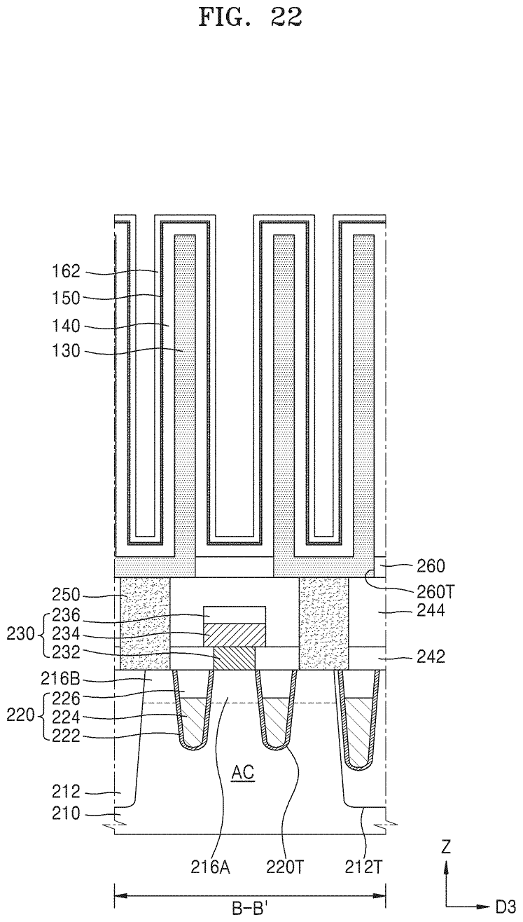

Referring to FIG. 22, a template layer 150 and a first upper electrode 162 may be formed on the dielectric layer structure 140.

In example embodiments, as described with reference to FIG. 13, a first upper electrode 162 including niobium nitride may be formed on the second dielectric layer 144 by a CVD process, an MOCVD process, an ALD process, an MOALD process, or the like. For example, in a process for forming the first upper electrode 162, a precursor including niobium may be oxidized, or a portion of the first upper electrode 162 placed adjacent to the second dielectric layer 144 may be oxidized. In this case, a template layer 150 including niobium oxide may be formed at the interface between the first upper electrode 162 and the second dielectric layer 144 with a first thickness t1 (see FIG. 10) that is relatively thin. For example, the first thickness t1 may be about 1 to 10 Å, but is not limited thereto. The first thickness t1 may vary according to a kind of the precursor used in the process of forming the first upper electrode 162, an atmosphere for forming the first upper electrode 162, a material composition of the second dielectric layer 144, and the like.

In other embodiments, as described with reference to FIG. 14, a template layer 150 including niobium oxide may be first formed on the second dielectric layer 144 by a CVD process, an MOCVD process, an ALD process, an MOALD process, or the like. For example, until the template layer 150 including niobium oxide is formed with a first thickness t1 of about 1 to 10 Å, a precursor including niobium (Nb) and a reactant including oxygen (O) may be alternately and repeatedly supplied. Afterwards, a first upper electrode 162 including niobium nitride may be formed on the template layer 150 by a CVD process, an MOCVD process, an ALD process, an MOALD process, or the like. For example, a precursor including niobium (Nb) and a reactant including nitrogen (N) may be alternately and repeatedly supplied to form the first upper electrode 162.

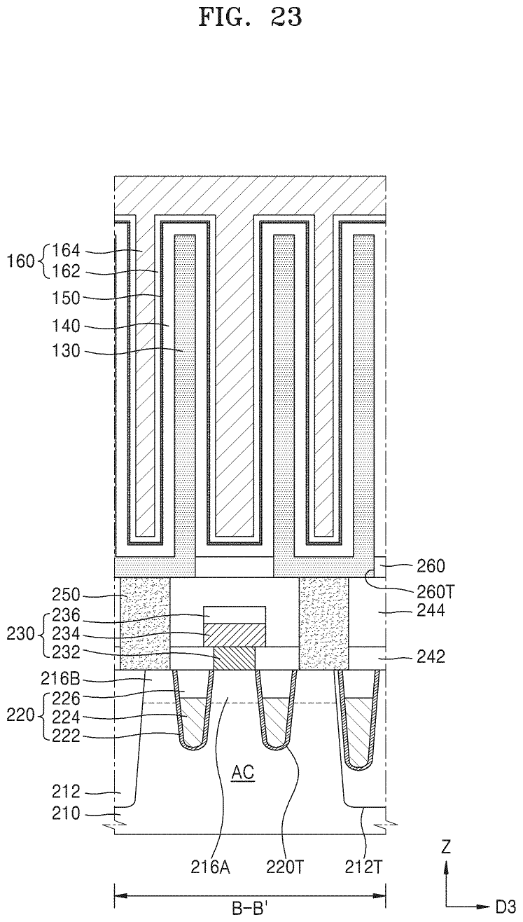

Referring to FIG. 23, a second upper electrode 164 may be formed on the first upper electrode 162. The second upper electrode 164 may completely fill the space defined by the inner wall of the lower electrode 130 on the first upper electrode 162.

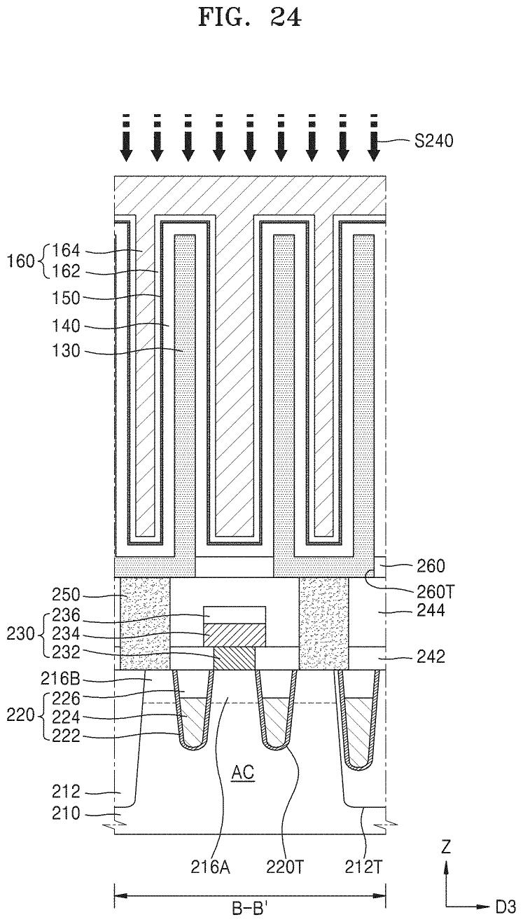

Referring to FIG. 24, a heat treatment process (S240) may be performed on the substrate 210 on which the second upper electrode 164 is formed.

In example embodiments, the heat treatment process (S240) may be performed at a temperature of about 200° C. to 500° C. for several minutes to several hours, but is not limited thereto. In some example embodiments, the second dielectric layer 144 may be crystallized to have a tetragonal crystal phase in the course of performing the heat treatment process (S240). In this case, the template layer 150 placed on an entire top surface of the second dielectric layer 144 may serve as a crystallization inducing layer for preferential orientation of the second dielectric layer 144.

In other embodiments, some thickness of the first upper electrode 162 may be oxidized to increase the thickness t1 (see FIG. 10) of the template layer 150 in the course of performing the heat treatment process (S240).

The semiconductor device 200 may be completed by performing the above-described process.

According to the above-described method of manufacturing the semiconductor device 200, the template layer 150 including niobium oxide during the heat treatment process (S240) may serve as a crystallization inducing layer which crystallizes the hafnium oxide to have a tetragonal crystal phase. In addition, the template layer 150 may serve as a protective layer to reduce or prevent the dielectric layer structure 140 from being damaged or penetrating materials such as reactants including nitrogen into the dielectric layer structure 140. The semiconductor device 200 may have a relatively high capacitance and excellent electrical characteristics.

According to the inventive concepts, a template layer including niobium oxide may be placed on a dielectric layer structure including hafnium oxide, and the template layer may serve as a crystallization inducing layer which crystallizes the hafnium oxide to have a tetragonal crystal phase during the heat treatment process. In addition, the template layer may serve as a protective layer to reduce or prevent damage to the dielectric layer structure or penetration of the reactive material into the dielectric layer structure in the process of forming the upper electrode. Accordingly, the semiconductor device may have a relatively high capacitance and excellent electrical characteristics.

As described above, example embodiments have been disclosed in the drawings and specification. While the embodiments have been described herein with reference to particular terms, it should be understood that they have been used only for the purpose of describing the technical idea of the inventive concepts and not for limiting the scope of the inventive concepts as defined in the claims. Therefore, those skilled in the art will appreciate that various modifications and equivalent embodiments are possible without departing from the scope of the inventive concepts. Accordingly, the true scope of protection of the inventive concepts should be determined by the technical idea of the appended claims.

While the inventive concepts have been particularly shown and described with reference to embodiments thereof, it will be understood that various changes in form and details may be made therein without departing from the spirit and scope of the following claims.

What is claimed is:

1. A semiconductor device comprising:
a lower electrode on a substrate;
a dielectric layer structure on the lower electrode and comprising hafnium oxide having a tetragonal crystal phase;
a template layer on the dielectric layer structure and comprising niobium oxide (NbOₓ, 0.5≤x≤2.5); and
an upper electrode structure comprising a first upper electrode and a second upper electrode on the template layer.

2. The semiconductor device of claim 1, wherein the dielectric layer structure comprises:
a first dielectric layer on the lower electrode and comprising a first dielectric material; and
a second dielectric layer on the first dielectric layer and comprising a second dielectric material,
wherein the second dielectric material comprises hafnium oxide having a tetragonal crystal phase.

3. The semiconductor device of claim 2, wherein an entire top surface of the second dielectric layer is in contact with the template layer.

4. The semiconductor device of claim 2, wherein the dielectric layer structure exhibits a peak of 30.48°+/−0.2° from the {101} plane of a tetragonal crystal structure of the second dielectric layer in an X-ray diffraction analysis.

5. The semiconductor device of claim 1, wherein the template layer has a thickness of about 1 to about 10 angstroms (Å).

6. The semiconductor device of claim 1, wherein the first upper electrode comprises niobium nitride (NbN_{y}, 0.5≤y≤1.0).

7. The semiconductor device of claim 1, wherein an entire top surface of the template layer is in contact with the first upper electrode.

8. The semiconductor device of claim 2, wherein the first dielectric material comprises at least one of zirconium oxide, aluminum oxide, aluminum silicon oxide, titanium oxide, yttrium oxide, scandium oxide, and lanthanide oxide.

9. The semiconductor device of claim 2, wherein the dielectric layer structure further comprises:
a third dielectric layer between the first dielectric layer and the second dielectric layer and comprising a third dielectric material different from the second dielectric material,
wherein the third dielectric material comprises at least one of zirconium oxide, aluminum oxide, aluminum silicon oxide, titanium oxide, yttrium oxide, scandium oxide, and lanthanide oxide.

10. The semiconductor device of claim 9, wherein the dielectric layer structure further comprises:
a fourth dielectric layer between the second dielectric layer and the third dielectric layer and comprising a fourth dielectric material different from the second dielectric material,
wherein the fourth dielectric material comprises at least one of zirconium oxide, aluminum oxide, aluminum silicon oxide, titanium oxide, yttrium oxide, scandium oxide, and lanthanide oxide.

11. The semiconductor device of claim 2, wherein the dielectric layer structure further comprises:
a third dielectric layer between the first dielectric layer and the second dielectric layer and comprising a third dielectric material,
wherein the third dielectric material comprises hafnium oxide having a tetragonal crystal phase.

12. The semiconductor device of claim 1, wherein the dielectric layer structure comprises:
a second dielectric layer on the lower electrode and comprising a second dielectric material,
wherein the template layer is directly on a top surface of the second dielectric layer.

13. A semiconductor device comprising:
a lower electrode structure on a substrate and comprising a first lower electrode and a second lower electrode;
a template layer on the lower electrode structure and comprising niobium oxide (NbOₓ, 0.5≤x≤2.5);
a dielectric layer structure on the template layer and comprising hafnium oxide having a tetragonal crystal phase; and
an upper electrode structure on the dielectric layer structure.

14. The semiconductor device of claim 13, wherein the dielectric layer structure comprises:
a second dielectric layer on the template layer and comprising a second dielectric layer comprising a second dielectric material, and
a first dielectric layer on the second dielectric layer and comprising a first dielectric layer comprising a first dielectric material, wherein the second dielectric material comprises hafnium oxide having a tetragonal crystal phase.

15. The semiconductor device of claim 14, wherein an entire bottom surface of the second dielectric layer is in contact with the template layer, and
an entire bottom surface of the template layer contacts the second lower electrode.

16. The semiconductor device of claim 14, wherein the second lower electrode comprises niobium nitride (NbN_{y}, 0.5≤y≤1.0).

17. A semiconductor device comprising:
a contact structure on a substrate; and
a capacitor structure on the contact structure,
wherein the capacitor structure comprises:
a lower electrode electrically connected to the contact structure;
a dielectric layer structure on the lower electrode and comprising hafnium oxide having a tetragonal crystal phase;
a template layer on the dielectric layer structure and comprising niobium oxide (NbOₓ, 0.5≤x≤2.5); and
an upper electrode structure comprising a first upper electrode and a second upper electrode on the template layer.

18. The semiconductor device of claim 17, wherein the template layer has a thickness of about 1 to about 10 angstroms (Å).

19. The semiconductor device of claim 17, wherein the dielectric layer structure comprises:
a first dielectric layer on the lower electrode and comprising a first dielectric layer comprising a first dielectric material; and
a second dielectric layer on the first dielectric layer and comprising a second dielectric layer comprising a second dielectric material,
wherein the second dielectric material comprises hafnium oxide having a tetragonal crystal phase,
wherein an entire top surface of the second dielectric layer is in contact with the template layer.

20. The semiconductor device of claim 19, wherein the dielectric layer structure exhibits a peak of 30.48°+/−0.2° from the {101} plane of a tetragonal crystal structure of the second dielectric layer in an X-ray diffraction analysis.
